(19) United States
(12) Patent Application Publication
(10) Pub. No.: US 2026/0180284 A1
(43) Pub. Date: Jun. 25, 2026

(54) OPTICALLY PUMPED MICROCHIP LASER AND A METHOD FOR GENERATING ELECTROMAGNETIC LASER RADIATION

(71) Applicant: Picophotonics Ltd., Tampere (FI)

(72) Inventors: Antti HÄRKÖNEN, Tampere (FI); Antti RANTANIEMI, Tampere (FI)

(21) Appl. No.: 19/001,183

(22) Filed: Dec. 24, 2024

(51) Int. Cl. H01S 5/06; G02B 3/00; H01S 5/02255; H01S 5/028

(52) U.S. Cl. CPC H01S 5/0601; H01S 5/02255; H01S 5/028; G02B 3/0087

(57) ABSTRACT

The present invention relates to an optically pumped microchip laser comprising: a pump lens; a gain element, wherein the gain element comprises a first end facet and a second end facet, wherein the gain element comprises a gain section, and wherein the gain section during operation of the microchip laser generates electromagnetic laser radiation; an output coupling reflective structure on the first end facet, wherein the output coupling reflective structure has a first reflectivity for the laser radiation; and a semiconductor saturable absorber mirror at the second end facet, wherein the semiconductor saturable absorber mirror comprises a saturable absorber section and a mirror section, and wherein the mirror section has a second reflectivity for the laser radiation, wherein the second reflectivity is larger than the first reflectivity; wherein the pump lens is arranged and positioned such that during operation of the microchip laser electromagnetic pump radiation is focused by the pump lens through the output coupling reflective structure into the gain element. According to the present invention the pump lens is a cylindrical Gradient Index lens comprising a cylinder axis, a first end surface and a second end surface, wherein the Gradient Index lens is arranged and positioned such that during operation of the microchip laser the pump radiation exits the Gradient Index lens through the second end surface, wherein the second end surface forms an angle with the cylinder axis different from 90 degrees, and wherein the gain element and the Gradient Index lens are positioned relative to each other such that the laser radiation exiting the gain element through the output coupling reflective structure is reflected at the second end surface such that the laser radiation bypasses the gain element.

### FIELD OF DISCLOSURE

The present invention relates to an optically pumped microchip laser comprising a pump lens; a gain element, wherein the gain element comprises a first end facet and a second end facet, wherein the gain element comprises a gain section, and wherein the gain section during operation of the microchip laser generates electromagnetic laser radiation; an output coupling reflective structure on the first end facet, wherein the output coupling reflective structure has a first reflectivity for the laser radiation; and a semiconductor saturable absorber mirror at the second end facet, wherein the semiconductor saturable absorber mirror comprises a saturable absorber section and a mirror section, and wherein the mirror section has a second reflectivity for the laser radiation, wherein the second reflectivity is larger than the first reflectivity; wherein the pump lens is arranged and positioned such that during operation of the microchip laser electromagnetic pump radiation is focused by the pump lens through the output coupling reflective structure into the gain element.

Furthermore, the present invention relates to a method for generating electromagnetic laser radiation in an optically pumped microchip laser, comprising the following steps: providing a pump laser, a pump lens, an output coupling reflective structure, and a semiconductor saturable absorber mirror, wherein the gain element comprises a first end facet and a second end facet, wherein the gain element comprises a gain section, wherein the output coupling reflective structure is provided on the first end facet, wherein the output coupling reflective structure has a first reflectivity for the laser radiation, wherein the semiconductor saturable absorber mirror is provided at the second end facet, wherein the semiconductor saturable absorber mirror comprises a saturable absorber section and a mirror section, and wherein the mirror section has a second reflectivity for the laser radiation, wherein the second reflectivity is larger than the first reflectivity; generating and emitting electromagnetic pump radiation by the pump laser; focusing the pump radiation by the pump lens through the output coupling reflective structure into the gain element; and generating the laser radiation in the gain section.

### BACKGROUND

An optically-pumped laser, wherein the laser resonator including the gain material is formed of solid-state material including all cavity elements, like a high-reflective mirror, an output coupler mirror and other optional cavity elements, are monolithically integrated is typically denoted as a “microchip laser”. In a microchip laser there are no air gaps between different components of the resonator or cavity. In contrast to a conventional external cavity laser, there is no need for an active alignment of any elements in the resonator. Due to the simple monolithic architecture a microchip laser is generally very robust and available at moderate cost.

The monolithic architecture of a microchip laser enables a practical way to implement generation of short pulse laser radiation by integrating a Q-switching element into the microchip structure. Typically, a Q-switching element comprises doped glass, doped crystal material, bulk semiconductor material or a semiconductor structure containing quantum wells or quantum dots.

A microchip laser comprising a Q-switching element is typically pumped by electromagnetic pump radiation from one end and the electromagnetic laser radiation exits the microchip structure at the other end. This configuration allows a generation of high energy electromagnetic pulses of a typical pulse duration for a sub-nanosecond to some tens of nanoseconds.

Enhanced pulse properties can be achieved by integration of a semiconductor saturable absorber mirror (SESAM) into the microchip laser structure. In particular, SESAMs allow generation of shorter optical pulses when compared to other designs.

A SESAM is an integrated element providing two functionalities in a single component, namely Q-switching and reflection. Thus, a SESAM comprises a saturable absorber section and a mirror section. The two sections of the SESAM are typically processed on a thin semiconductor substrate wafer. Semiconductor manufacturing is highly precise and modern manufacturing equipment allows fabrication of multiple large diameter wafers in one run at considerably low cost per component.

The thickness of a SESAM layer structure is typically only a few micrometers, which is significantly smaller than the thickness of a conventional solid-state saturable absorber. The thinner extension of a SESAM allows implementing a shorter cavity length and thus enables shorter optical pulses.

Furthermore, SESAMs when compared to conventional solid-state saturable absorbers, allow highly accurate tailoring of design parameters (such as saturation fluence and amount of saturable absorption, for example) to suit a particular application of the microchip laser. For example, SESAMs can allow shorter pulses and higher pulse repetition rates than commonly obtained with conventional solid-state Q-switching elements. These degrees of freedom in the design of SESAMs make them highly interesting components for Q-switched microchip lasers.

Still, there is an essential drawback associated with a SESAM in a Q-switched microchip laser. The semiconductor substrate and the semiconductor materials used to implement the mirror section prevent, or at least significantly complicate a transmission of the electromagnetic pump radiation as well as the generated electromagnetic laser radiation through the SESAM. Therefore, it is challenging to design an optically pumped microchip laser to include a SESAM in a linear configuration as described above. Thus, typically microchip lasers including a SESAM are arranged such that the laser radiation exits the laser resonator at the same end at which the pump radiation enters the resonator.

Consequently, in many designs of optically pumped microchip lasers including a SESAM, a dichroic mirror is positioned between the pump lens and the gain element to couple out the generated laser radiation. However, inserting a dichroic mirror at this position and still achieving an acceptable footprint of the overall design is challenging. In addition, the dichroic mirror requires a further alignment step during production of the laser.

### SUMMARY

It is an object of the present invention to provide an optically pumped microchip laser comprising a comparatively small footprint. Furthermore, it is an objective of the present invention to provide an optically pumped microchip laser of a sufficient gain and beam quality. Finally, it is an object of the present invention to allow a design of the microchip laser leading to optical pulses having a shorter pulsed duration.

At least one of the above objects is solved by an optically pumped microchip laser according to independent claim 1. In order to solve at least one of these objects, the pump lens in the above described optically pumped microchip laser is a cylindrical Gradient Index (GRIN) lens comprising a cylinder axis, a first end surface and a second end surface. The GRIN lens is arranged and positioned such that, during operation of the microchip laser, the pump radiation exits the GRIN lens through the second end surface, wherein the second end surface forms an angle with the cylinder axis different from 90 degrees, and wherein the gain element and the GRIN lens are positioned relative to each other such that the laser radiation exiting the gain element through the output coupling reflective structure is reflected at the second end surface such that the laser radiation bypasses the gain element.

This overall architecture of the microchip laser according to the present invention avoids the need for an additional dichroic element between the pump lens and the gain element and simultaneously enables to provide a laser radiation with the required quality of parameters.

It is the basic concept of the present invention to use a tilted second end surface of the GRIN lens to reflect the laser radiation in order to bypass the gain element. This reduces overall footprint of the laser when compared to a design of the prior art, wherein an additional mirror is placed between the pump lens and the gain element.

In the prior art there are also examples of microchip lasers avoiding use of a dichroic mirror separating pump radiation and laser radiation, by pumping the microchip laser from such a large angle, that the generated laser radiation is able to bypass the pump optics unhindered without obstruction. Also when compared to such prior art designs, the concept of the present invention has clear advantages. Using the second end surface of the GRIN lens as a reflector for the laser radiation avoids the necessity for an excessive tilt of the gain element relative to the beam axis of the pump radiation, allowing the pump and the generated signal laser beam to be closely co-axial. Thus, the design according to the present invention allows a longer gain section leading to a higher gain and allowing a wider freedom of laser design.

The microchip laser structure according to the present invention is a monolithic structure comprising the gain element, the SESAM at the second end facet of the gain element as well as an output coupling reflective coating on the first end facet of the gain element. In the present disclosure this monolithic structure will also be referred to as the microchip structure.

Describing that the SESAM is provided at the second end facet does not exclude that a further element, e.g. a pump reflective structure, is provided between the gain element and the SESAM as long as the gain element and the SESAM form the monolithic microchip structure.

The gain element necessarily requires a gain section providing optical gain once pumped with the pump radiation. In an embodiment of the present invention the gain section of the gain element comprises doped glass or a doped crystal material.

In an embodiment the gain section comprises an Nd, Er or Yb doped glass or an Nd, Er or Yb doped crystal. In an embodiment the gain section comprises a Nd:YVO₄ crystal pumped by pump radiation at 808 nm wavelength and emitting laser radiation at a wavelength of 1064 nm (or 914 nm or 1342 nm, for example). In an embodiment the gain section comprises Er, Yb-doped glass pumped by pump radiation at a wavelength from 915 nm to 980 nm and emitting laser radiation at a wavelength in a range of about 1.5 μm. In a 15 further embodiment the gain section comprises a Th:Hm doped crystal.

In an embodiment of the present invention the gain element in addition to the gain section comprises a passive section. This passive section does not provide any optical gain. In an embodiment the passive section is a section for thermal management of the microchip structure. In an embodiment this passive section serves as a heatsink and mechanical support against thermal stress for heat generated in any one of the elements of the microchip structure.

In an embodiment of the present invention, the passive section of the gain element comprises the first end facet of the gain element such that the output coupling reflective structure is provided on the passive section. In this arrangement the gain section is positioned between the passive section and the SESAM.

The mirror section of the SESAM is the high reflecting end mirror of the laser resonator formed between the mirror section of the SESAM and the output coupling reflective structure on the first end facet of the gain element. As the output coupling reflective structure operates as the output coupler for the laser radiation it has a lower reflectivity than the mirror section of the SESAM. In an embodiment of the present invention the mirror section of the SESAM is a Distributed Bragg Reflector (DBR).

In an embodiment the geometry of the resonator defined by the output coupling reflective structure and the mirror section of the SESAM is a planar-planar-configuration, i.e. both reflectors are planar. However, embodiments are feasible, wherein the output coupling reflective structure has a curved shape.

In an embodiment the SESAM is optically bonded onto the second end facet of the gain element.

The output coupling reflective structure is manufactured onto the first end facet of the gain element. In an embodiment of the present invention the output coupling reflective structure is coated onto the first end facet of the gain element, i.e. the output coupling reflective structure is an output coupling reflective coating. In an alternative embodiment, the output coupling reflective structure is bonded onto the first end facet after separate manufacturing of the output coupling reflective structure on the one hand and the gain element on the other hand.

In principle, a reflection at the air interface at the second end surface of the GRIN lens may be sufficient in order to reflect the laser radiation emitted from the microchip laser structure. However, a lens coating may enhance reflection. Thus, in an embodiment of the present invention a reflective lens coating is provided on the second end surface of the GRIN lens, wherein in the reflective lens coating has a third reflectivity for the laser radiation.

In the embodiment of the present invention the third reflectivity is larger than the first reflectivity.

An optical coating in the sense of the present invention, in particular the output coupling reflective coating on the first end facet of the gain element and the reflective lens coating on the second end surface of the GRIN lens can comprise one or more coating layers as required to provide the desired reflectivity in a selected wavelength range.

In an embodiment of the present invention an anti-reflection pump coating is provided on the reflective lens coating or a dichroic coating is provided on the second end surface, wherein the dichroic coating implements the reflective lens coating and the anti-reflective pump coating. An anti-reflective pump coating enhances the power of the pump radiation exiting the GRIN lens.

In an embodiment of the present invention the angle between the second end surface and the cylinder axis is in a range from 70 degrees to less than 90 degrees, preferably in a range from 75 degrees to less than 90 degrees, and preferably in a range from 80 degrees to less than 90 degrees. In an embodiment of the present invention the angle amounts to 82 degrees.

A change in the beam direction of the laser radiation emitted from the microchip structure is changed by the angle between the second end surface of the GRIN lens and the cylinder axis of the GRIN lens. Thus, in principle the first end facet of the gain element (or a tangent of the first end surface in case of a curved end surface) may be perpendicular to the cylinder axis of the GRIN lens. However, due to the tilt of the second end surface with respect to the cylinder axis the beam axis of the pump radiation exiting the GRIN lens may no longer follow the direction of the cylinder axis, but is refracted away from the cylinder axis by a small angle.

Thus, in an embodiment of the present invention an angle is provided between the cylinder axis and the first end facet, which angle is different from 90 degrees. In an embodiment the angle formed between the cylinder axis and the first end facet is in a range from 75 degrees to less than 90 degrees. This angle is straightforward to be measured once the first end facet of the gain element is planar. Once the first end facet is curved the angle is determined as the angle between the cylinder axis and a tangential plane to the first end facet at a point on the first end facet at which the laser radiation exits the gain element. By providing an angle different from 90 degrees between the cylinder axis and the first end facet it is possible to co-axially align or to approximately co-axially align the pump radiation and the laser radiation in the gain section.

Providing the GRIN lens with a tilted second end surface relative to the cylinder axis allows to use the second end surface as a reflective surface avoiding the necessity for placing an additional optical element between the pump lens and the gain element to separate the pump radiation and the generated laser radiation. Consequently, in an embodiment of the present invention a distance between the second end surface of the GRIN lens and the first end facet of the gain element is equal to smaller than 15 mm, preferably is equal to or smaller than 10 mm, and preferably is equal to or smaller than 5 mm.

The distance between the second end surface of the GRIN lens and the first end facet of the gain element in an embodiment is determined as a distance between an intersection between the cylinder axis and the second end surface on the one hand and an intersection of the pump beam and the first end facet of the gain element.

In an embodiment of the present invention the microchip laser during operation generates optical pulses comprising a pulse repetition rate equal to or larger than 100 kHz, preferably equal to or larger than 500 kHz, and preferably equal to or larger than 1 MHz. Such high repetition rates are difficult to achieve by the microchip laser designs of the prior art.

The tilt angle of the second end surface of the GRIN lens relative to the cylinder axis to the GRIN lens avoids an excessive tilt between the pump radiation and laser radiation in the gain element. Thus, a gain section with a reasonable length may be provided, while still providing a fair overlap of the pump radiation and generated laser radiation. In an embodiment of the present invention the gain section of the gain element has a thickness equal to or larger than 100 μm, preferably equal to or larger than 400 μm, and preferably equal to or larger than 800 μm. In an embodiment the gain section of the gain element has a thickness in a range from 100 μm to 400 μm, preferably addressing a wavelength of 1064 nm for the laser radiation. In an embodiment the gain section of the gain element has a thickness in a range from 1 mm to 4 mm, preferably addressing a wavelength of 1535 nm for the laser radiation.

In an embodiment of the present invention no further optical component separating the pump radiation and the laser radiation is provided between the output coupling reflective structure and the second end surface of the GRIN lens or between the output coupling reflective structure and the reflective lens coating or between the output coupling reflective structure and the anti-reflective pump coating. This drastically reduces the footprint of the overall microchip laser.

In a further embodiment of the present invention a pump reflective structure is provided between the SESAM and the gain element to reflect the pump radiation back into the gain section.

In an embodiment, the pump reflective structure is bonded onto the SESAM or onto the gain element after separate manufacturing of the pump reflective structure on the one hand and the SESAM or the gain element on the other hand.

In an embodiment, the pump reflective structure is a pump reflective coating coated onto the absorber section of the SESAM or onto the gain element.

In an alternative embodiment, the pump reflective structure is implemented in the mirror section of the SESAM to reflect the pump radiation back into the gain section.

Reflecting the pump radiation which has already passed the gain section for a first time back into the gain section enhances the pumping efficiency of the microchip laser and reduces pump induced local heating of the SESAM.

In a further embodiment of the present invention the microchip laser comprises a pump laser, wherein the pump laser is arranged such that during operation of the microchip laser, the pump laser generates and emits the pump radiation, and wherein the pump laser and the GRIN lens are arranged and positioned such that the pump radiation emitted from the pump laser enters into the GRIN lens through the first end surface.

In an embodiment of the invention the pump laser is a laser diode, preferably a multimode laser diode.

Common applications for an optically pumped microchip laser according to the present invention include a time-of-flight measurement for range finding, a LIDAR, micromachining, marking and a seed source for power amplifiers.

At least one of the above objects is also solved by a method for generating electromagnetic laser radiation according to independent claim 14. In order to solve at least one of these objects, the pump lens in the above-mentioned method is a cylindrical GRIN lens comprising a cylinder axis, a first end surface and a second end surface, wherein in a direction of propagation from the pump laser to the gain element, the pump radiation exits the GRIN lens through the second end surface, and wherein the second end surface forms an angle with the cylinder axis different from 90 degrees. The method according to the present invention further comprises the step of reflecting the laser radiation exiting the gain element through the output coupling reflective coating at the second end surface such that the laser radiation bypasses the gain element.

To the extent that aspects of the invention are described above with regard to the optically pumped microchip laser, these also apply to the corresponding method for generating electromagnetic laser radiation and vice versa. To the extent that the method is carried out with an optically pump microchip laser according to this invention, the optically pump microchip laser comprises the appropriate features for this purpose. In particular, embodiments of the laser are suitable for carrying embodiments of the method.

### BRIEF DESCRIPTION OF THE DRAWING

Further advantages, features and applications of the present invention will become apparent from the following description of an embodiment and the corresponding FIGURE attached. The foregoing as well as the following detailed description of embodiments will be better understood when read in conjunction with the appended drawings. In the FIGURES like elements are denoted by identical reference numbers.

FIG. 1 is a schematic representation of an embodiment of an optically pumped microchip laser according to the present invention.

### DETAILED DESCRIPTION

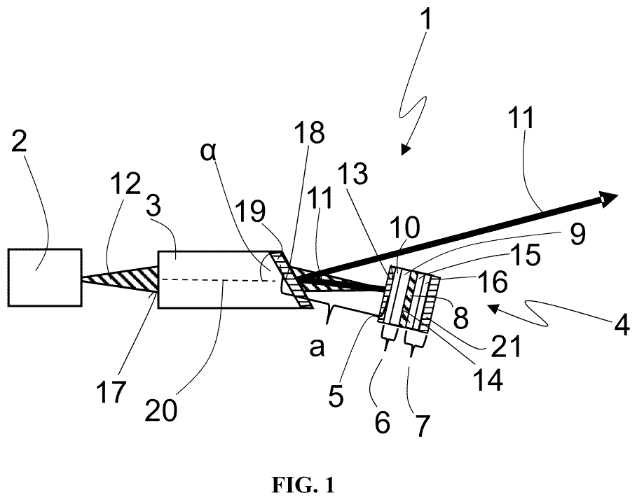

The microchip laser 1 drawn in FIG. 1 includes three major components, namely a pump laser diode 2, a GRIN lens 3 as the pump lens of the arrangement 1, and a microchip structure 4. Each of these three components 2, 3 and 4 of the optically pumped microchip laser 1 are individual and separate entities positioned relative to each other.

The GRIN lens 3 as well as the microchip structure 4 contain or carry more than one functional element of the microchip laser 1.

The design of the microchip laser 1 is dominated by the requirements of the microchip structure 4. In the embodiment of FIG. 1 the microchip structure 4 comprises an output coupling reflective coating 5, a gain element 6, a pump reflective coating 8, and a semiconductor saturable absorber mirror (SESAM) 7.

The gain element 6 in turn consists of a gain section 9 and a passive section 10. The gain of the microchip structure 4 is provided in the gain section 9 by stimulated emission of the electromagnetic laser radiation 11. The passive section 10 is a block of material being transparent for the laser radiation 11 as well as for the electromagnetic pump radiation 12. The gain element 6 comprises a first end facet 13 and a second end facet 14. On the first end facet 13, the output reflective coating 5 is coated as a first mirror of the resonator required to provide laser radiation by the microchip structure 4.

The SESAM 7 consists of a saturable absorber section 15 and a mirror section 16 grown on a semiconductor substrate 21. The saturable absorber section 16 acts as a Q-switch in the microchip structure 4 to generate short optical pulses in the microchip laser 1. In the embodiment illustrated the saturable absorber section 16 is a multiple quantum-well structure.

A pump reflective coating 8 is coated onto the SESAM 7. For assembly of the gain element 6 and the SESAM 7 carrying the pump reflective coating 8, the pump reflective coating 8 is optically bonded onto the gain element 6.

In the embodiment illustrated in FIG. 1 the gain section 9 is Er, Yb doped glass and the passive section 10 is an undoped glass. The thickness of the gain section 9 is 3 mm.

In the embodiment shown, the pump laser diode 2 generates electromagnetic pump radiation 12 at 940 nm. In order to enable lasing of the microchip laser structure 4, the pump radiation 12 generated by the pump laser diode 2 is focused into the gain element 6 using the GRIN lens 3. The pump radiation 12 generated by the pump laser diode 2 enters the GRIN lens 3 through the first end surface 17 of the GRIN lens.

Due to its design, the laser radiation 11 generated in the microchip structure 4 is emitted from the microchip laser structure 4 through the output coupling reflective coating 5 on the first end facet 13. Thus, the output coupling reflective coating 5 has a first reflectivity being smaller than a second reflectivity of the mirror section 16 of the semiconductor saturable absorber mirror 7. The output coupling reflective coating 5 and the mirror section 16 together define the resonator required to generate laser radiation 11 in the microchip structure 4.

In the embodiment described the microchip laser structure 4 generates short optical pulses at a wavelength of 1535 nm, having a pulse duration of 6 ns and a repetition rate of 1 kHz.

In an alternative embodiment not illustrated in the FIGURES the gain section 9 is a Nd:YVO₄ crystal. This embodiment well works without a passive section 10 due to the comparatively good thermal conductivity of the Nd:YVO₄. For this embodiment the pump radiation 12 has a wavelength of 808 nm. The gain section has a length of 200 μm. The laser radiation 11 has a wavelength of 1064 nm, a pulse duration of 200 ps and a repetition rate of 200 kHz.

In order to guide the laser radiation 11 out of the microchip laser 1, the GRIN lens 3 serves as a mirror for the laser radiation 11. By this design no further optical element to separate the pump radiation and the generated laser radiation, is required between the GRIN lens 3 and the microchip structure 4. Avoiding any additional optical element between the GRIN lens 3 and the microchip structure 4, simplifies the manufacturing process and allows to reduce the distance a between the second end surface of the GRIN lens 3 and the first end facet 13 of the gain element 6 to a value smaller than 5 mm.

In the implementation illustrated by FIG. 1, reflection of the laser radiation 11 at the second end surface 18 of the GRIN lens 3 is predominantly provided by the reflective lens coating 19 on the second end surface 18. This is still to be understood a reflection “at the second end surface 18”.

The reflection at the second end surface 18 of the GRIN lens 3 must be provided such that the laser radiation 11 bypasses the gain element 6 and all further components 5, 7, and 8 of the microchip structure 4 in order to avoid losses. Therefore, the second end surface 18 of the GRIN lens 3 forms an angle α with a cylinder axis 20 of the GRIN lens 3, which angle α is different from 90 degrees. In the embodiment illustrated in FIG. 1, this angle α is approximately 82 degrees. The angle α is measured as the smaller angle between the cylindrical axis 20 and the second end surface 18 of the GRIN lens 3.

In addition, the coating 19 on the second end surface 18 of the GRIN lens is an anti-reflective pump coating (could also be denoted a high transmissive coating). I.e. the coating 19 is high reflective for the lase radiation 11 and anti-reflective for the pump radiation 12. This anti-reflective pump coating reduces reflective losses of the electromagnetic pump radiation 12 at the interface when exiting the GRIN lens 3.

Tilting the second end surface 18 with respect to the cylinder axis 20, leads to a refraction of the pump radiation 12 away from the cylinder axis 20 when the pump radiation 12 exits the GRIN lens 3. In order to accommodate for this deflection of the pump radiation 12, the angle formed between the cylinder axis 20 and the facet 13 of the gain element 6 is different from 90 degrees. In the implementation illustrated by FIG. 1, this angle amounts to approximately 5 degrees.

By tilting the microchip structure 4 with respect to the cylinder axis 20, an optimized overlap between the pump radiation 12 and the laser radiation 11 in the gain section 9 can be maintained despite the fact that the pump radiation 12 is refracted relative to the cylinder axis 20. The optimized overlap in turn allows to provide the gain section 9 with a comparatively large thickness of 900 μm in the given example.

The pump reflective coating 8 between the gain element 6 and the SESAM 7 reflects the pump radiation 12 which was transmitted through the gain element 6 the microchip structure 4 back into the gain section 9. This back reflection of the pump radiation 12 reduces pump related heating of the SESAM and increases the efficiency of the generation of the laser radiation 11 in the microchip structure 4.

For the purposes of the original disclosure, it is pointed out that all features as they become apparent to a person skilled in the art from the present description, the drawings and the claims, even if they have been specifically described only in connection with certain further features, can be combined both individually and in any desired combinations with other of the features or groups of features disclosed herein, unless this has been expressly excluded or technical circumstances render such combinations impossible or pointless. A comprehensive, explicit description of all conceivable combinations of features is omitted here only for the sake of brevity and readability of the description.

While the invention has been illustrated and described in detail in the drawings and the foregoing description, this illustration and description are merely exemplary and are not intended to limit the scope of protection as defined by the claims. The invention is not limited to the embodiments disclosed.

Variations of the disclosed embodiments will be apparent to those skilled in the art from the drawings, description and appended claims. In the claims, the word “comprising” does not exclude other elements or steps, and the indefinite article “a” does not exclude a plurality. The mere fact that certain features are claimed in different claims does not exclude their combination. Reference signs in the claims are not intended to limit the scope of protection.

### LIST OF REFERENCE NUMBERS

1 microchip laser
2 pump laser
3 GRIN lens
4 microchip structure
5 output coupling reflective coating
6 gain element
7 semiconductor saturable absorber mirror
8 pump reflective coating
9 gain section
10 passive section
11 laser radiation
12 pump radiation
13 first end facet
14 second end facet
15 saturable absorber section
16 mirror section
17 first end surface
18 second end surface
19 reflective lens coating
20 cylinder axis
21 semiconductor substrate
a distance between the second end surface and the first end facet
α angle between the cylinder axis and the first end facet

1. An optically pumped microchip laser (1) comprising
a pump lens,
a gain element (6),
wherein the gain element (6) comprises a first end facet (13) and a second end facet (14),
wherein the gain element (6) comprises a gain section (9), and
wherein the gain section (9) during operation of the microchip laser (1) generates electromagnetic laser radiation (11),
an output coupling reflective structure (5) on the first end facet (13),
wherein the output coupling reflective structure (5) has a first reflectivity for the laser radiation (11), and
a semiconductor saturable absorber mirror (7) at the second end facet (14),
wherein the semiconductor saturable absorber mirror (7) comprises a saturable absorber section (15) and a mirror section (16), and
wherein the mirror section (16) has a second reflectivity for the laser radiation (11), wherein the second reflectivity is larger than the first reflectivity,
wherein the pump lens is arranged and positioned such that during operation of the microchip laser (1) electromagnetic pump radiation (12) is focused by the pump lens through the output coupling reflective structure (5) into the gain element (6),
characterized in that
the pump lens is a cylindrical Gradient Index lens (3) comprising a cylinder axis (20), a first end surface (17) and a second end surface (18),
wherein the Gradient Index lens (3) is arranged and positioned such that during operation of the microchip laser (1) the pump radiation (12) exits the Gradient Index lens (3) through the second end surface (18),
wherein the second end surface (18) forms an angle (α) with the cylinder axis (20) different from 90 degrees, and
wherein the gain element (6) and the Gradient Index lens (3) are positioned relative to each other such that the laser radiation (11) exiting the gain element (6) through the output coupling reflective structure (5) is reflected at the second end surface (18) such that the laser radiation (11) bypasses the gain element (6).

2. The microchip laser (1) according to claim 1, wherein a reflective lens coating (19) is provided on the second end surface (18), wherein the reflective lens coating (19) has a third reflectivity for the laser radiation (11).

3. The microchip laser (1) according to claim 2, wherein an anti-reflective pump coating is provided on the reflective lens coating (19) or a dichroic coating is provided on the second end surface (18), wherein the dichroic coating implements the reflective lens coating (19) and the anti-reflective pump coating.

4. The microchip laser (1) according to claim 1, wherein the angle (α) between the second end surface (18) and the cylinder axis (20) is in a range from 70 degrees to less than 90 degrees, or in a range from 75 degrees to less than 90 degrees, or in a range from 80 degrees to less than 90 degrees.

5. The microchip laser (1) according to claim 1, wherein an angle formed between the cylinder axis (20) and the first end facet (13) is different from 90 degrees.

6. The microchip laser (1) according to claim 1, wherein a distance between the second end surface (18) of the Gradient Index lens (3) and the first end facet (13) of the gain element (6) is equal to or smaller than 15 mm, or is equal to or smaller than 10 mm, and preferably or is equal to or smaller than 5 mm.

7. The microchip laser (1) according to claim 1, wherein the microchip laser (1) during operation generates optical pulses comprising a pulse repetition rate equal to or larger than 100 kHz, or equal to or larger than 500 kHz, and preferably or equal to or larger than 1 MHz.

8. The microchip laser (1) according to claim 1, wherein the gain section has a thickness equal to or larger than 300 μm, or equal to or larger than 400 μm, or equal to or larger than 800 μm.

9. The microchip laser (1) according to claim 1, wherein no further optical component separating the pump radiation (12) and the laser radiation (11) is provided between the output coupling reflective structure (5) and the second end surface (18) of the Gradient Index lens (3) or between the output coupling reflective structure (5) and the reflective lens coating (19) or between the output coupling reflective structure (5) and the anti-reflective pump coating.

10. The microchip laser (1) according to claim 1, wherein a pump reflective structure (8) is provided between semiconductor saturable absorber mirror (7) and the gain element (6) to reflect the pump radiation (12) into the gain section (9) or the pump reflective structure (8) is implemented in the mirror section (16) to reflect the pump radiation (12) into the gain section (9).

11. The microchip laser (1) according to claim 1, wherein the gain element (6) comprises a passive section.

12. The microchip laser (1) according to claim 1, wherein the microchip laser (1) comprises a pump laser (2), wherein the pump laser (2) is arranged such that during operation of the microchip laser (1), the pump laser (2) generates and emits the pump radiation (12), and wherein the pump laser (2) and the Gradient Index lens (3) are arranged and positioned such that the pump radiation (12) emitted from the pump laser (2) enters into the Gradient Index lens (3) through the first end surface (17).

13. The microchip laser (1) according to claim 12, wherein the pump laser is a laser diode, and preferably is a multimode laser diode (2).

14. A method for generating electromagnetic laser radiation (11) in an optically pumped microchip laser, comprising the following steps
providing a pump laser (2), a pump lens (3), an output coupling reflective structure (5), and a semiconductor saturable absorber mirror (7),
wherein the gain element (6) comprises a first end facet (13) and a second end facet (14),
wherein the gain element (6) comprises a gain section (9),
wherein the output coupling reflective structure (5) is provided on the first end facet (13),
wherein the output coupling reflective structure (5) has a first reflectivity for the laser radiation (11),
wherein the semiconductor saturable absorber mirror (7) is provided at the second end facet (14),
wherein the semiconductor saturable absorber mirror (7) comprises a saturable absorber section (15) and a mirror section (16), and
wherein the mirror section (16) has a second reflectivity for the laser radiation (11), wherein the second reflectivity is larger than the first reflectivity;
generating and emitting electromagnetic pump radiation (12) by the pump laser (2);
focusing the pump radiation (12) by the pump lens through the output coupling reflective structure (5) into the gain element (6); and
generating the laser radiation (11) in the gain section (9);
characterized in that
the pump lens is a cylindrical GRIN lens (3) comprising a cylinder axis (20), a first end surface (17) and a second end surface (18), wherein in a direction of propagation from the pump laser (2) to the gain element (6), the pump radiation exits the GRIN lens (3) through the second end surface (18), and wherein the second end surface (18) forms an angle (α) with the cylinder axis (20) different from 90 degrees; and
the method further comprises the step of
reflecting the laser radiation (11) exiting the gain element (6) through the output coupling reflective structure (5) at the second end surface (18) such that the laser radiation (11) bypasses the gain element (6).
